(19) United States
(12) Patent Application Publication
(10) Pub. No.: US 2024/0188326 A1
(43) Pub. Date: Jun. 6, 2024

(54) DISPLAY DEVICE AND METHOD OF MANUFACTURING THE SAME

(71) Applicant: Samsung Display Co., Ltd., Yongin-si (KR)

(72) Inventors: Sungbae Ju, Yongin-si (KR); Sora Kim, Yongin-si (KR); Jeongseon Kim, Yongin-si (KR); Ahyeon Lee, Yongin-si (KR)

(21) Appl. No.: 18/464,048

(22) Filed: Sep. 8, 2023

(30) Foreign Application Priority Data
Dec. 2, 2022 (KR) 10-2022-0167027

(51) Int. Cl. H10K 59/12; H10K 59/122; H10K 59/35; H10K 59/80

(52) U.S. Cl. CPC H10K 59/1201; H10K 59/122; H10K 59/35; H10K 59/87; H10K 2102/302

(57) ABSTRACT

A display device includes: a display panel; a protection layer on the display panel and comprising a plurality of grooves each having an anchor shape, wherein the plurality of grooves comprise at least a first groove; a 1-1 layer arranged along at least a portion of an inner side surface of the first groove; and a plurality of transparent partition walls on the protection layer and comprising a first transparent partition wall, wherein the first transparent partition wall is arranged along the first groove and has a portion filling the first groove.

### CROSS-REFERENCE TO RELATED APPLICATION

The present application claims priority to and the benefit of Korean Patent Application No. 10-2022-0167027, filed on Dec. 2, 2022, in the Korean Intellectual Property Office, the entire disclosure of which is incorporated herein by reference.

### BACKGROUND

### 1. Field

Aspects of one or more embodiments relate to a display device and a method of manufacturing the same.

### 2. Description of the Related Art

A display device receives information regarding images and displays the images. Recently, as display devices have been relatively widely used, the issue of privacy regarding information displayed on the display device has arisen.

To address this issue, a display device with a more robust structure, in which a viewing angle is controlled by blocking side light and emitting vertical light, and a method of manufacturing the display device may be desired.

The above information disclosed in this Background section is only for enhancement of understanding of the background and therefore the information discussed in this Background section does not necessarily constitute prior art.

### SUMMARY

Aspects of one or more embodiments relate to a display device and a method of manufacturing the same, and for example, to a display device with a more robust structure, in which a viewing angle is controlled by blocking side light and emitting vertical light, and a method of manufacturing the display device.

To solve various problems including the above problem, one or more embodiments include a display device with a more robust structure, in which a viewing angle is controlled by blocking side light and emitting vertical light, and a method of manufacturing the display device. However, such a technical problem is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display device includes a display panel, a protection layer arranged on the display panel and including a plurality of grooves each having an anchor shape, wherein the plurality of grooves include at least a first groove, a 1-1 layer arranged along at least a portion of an inner side surface of the first groove, and a plurality of transparent partition walls arranged on the protection layer and including a first transparent partition wall, wherein the first transparent partition wall is arranged along the first groove and has a portion filling the inside of the first groove.

According to some embodiments, the display device may further include a 2-1 layer arranged along at least a portion of an outer side surface of the first transparent partition wall.

According to some embodiments, the 1-1 layer and the 2-1 layer may include the same material as each other.

According to some embodiments, the inner side surface of the first groove may include a 1-1 sub-inner side surface extending from a top surface of the protection layer in a direction toward the display panel and having a first width when viewed in a direction perpendicular to the display panel, and a 1-2 sub-inner side surface extending from the bottom of the 1-1 sub-inner side surface in the direction toward the display panel and having a second width that is greater than the first width when viewed in the direction perpendicular to the display panel.

According to some embodiments, the 1-1 layer may be arranged along the 1-2 sub-inner side surface.

According to some embodiments, when viewed in a direction perpendicular to the display panel, each of the plurality of grooves may have a different width for each location.

According to some embodiments, the plurality of grooves may further include a second groove spaced apart from the first groove.

According to some embodiments, the plurality of transparent partition walls may further include a second transparent partition wall arranged on the protection layer along the second groove and having a portion filling the inside of the second groove.

According to some embodiments, a distance between a top surface of the second transparent partition wall and a top surface of the display panel may be less than a distance between a top surface of the first transparent partition wall and the top surface of the display panel.

According to some embodiments, when viewed in a direction perpendicular to the display panel, an area of a top surface of the second transparent partition wall may be less than an area of a bottom surface of the second transparent partition wall.

According to some embodiments, the 2-1 layer may be arranged between an outer side surface of the second transparent partition wall and the outer side surface of the first transparent partition wall.

According to some embodiments, the 1-1 layer and the 2-1 layer may include the same material as each other.

According to some embodiments, the plurality of grooves may further include a third groove spaced apart from the second groove in a direction opposite to the first groove.

According to some embodiments, the plurality of transparent partition walls may further include a third transparent partition wall arranged on the protection layer along the third groove and having a portion filling the inside of the third groove.

According to some embodiments, a distance between a top surface of the third transparent partition wall and a top surface of the display panel may be greater than a distance between a top surface of the second transparent partition wall and the top surface of the display panel.

According to some embodiments, when viewed in a direction perpendicular to the display panel, the third transparent partition wall may be symmetrical to the first transparent partition wall with respect to the second transparent partition wall.

According to some embodiments, the display device may further include a 1-2 layer arranged along at least a portion of an inner side surface of the third groove.

According to some embodiments, the 1-2 layer may include the same material as the 1-1 layer.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a display panel of a display device according to some embodiments;

FIG. 2 is an equivalent circuit diagram of a pixel included in the display panel of FIG. 1;

FIG. 3 is a schematic cross-sectional view of a portion of the display panel of FIG. 1;

FIG. 4 is a schematic cross-sectional view of a display device according to some embodiments;

FIG. 5 is a schematic cross-sectional view of a display device according to some embodiments;

FIG. 6 is a schematic cross-sectional view of a display device according to some embodiments;

FIG. 7 is a schematic cross-sectional view of a display device according to a comparative example; and

FIGS. 8 to 18 are cross-sectional views sequentially showing a method of manufacturing the display device according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

Aspects of some embodiments will be described below in more detail with reference to the accompanying drawings. Those elements that are the same or are in correspondence with each other are rendered the same reference numeral regardless of the figure number, and redundant descriptions thereof are omitted.

It will be understood that, when an element, such as a layer, a film, a region, or a plate, is referred to as being “on” another element, it may be “directly on” the other element, or intervening elements may be present therebetween. In addition, sizes of elements in the drawings may be exaggerated or reduced for convenience of explanation. For example, because sizes and thicknesses of elements in the drawings are arbitrarily illustrated for convenience of explanation, the following embodiments are not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Hereinafter, a display device according to some embodiments will be described in more detail based on the above descriptions.

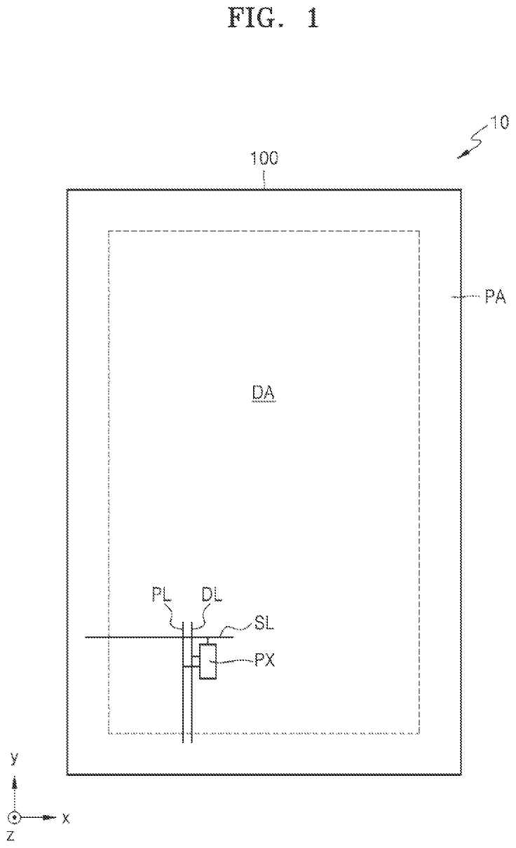

FIG. 1 is a schematic plan view of a display panel 10 of a display device according to some embodiments.

As shown in FIG. 1, a display device according to some embodiments may include the display panel 10. The display device may be any device including the display panel 10. For example, the display device may be a variety of devices, such as a smartphone, a tablet, a laptop, a television, a billboard, or any other electronic device capable of displaying images. A display device according to some embodiments includes thin-film transistors and capacitors, and accordingly, the thin-film transistors and the capacitors may be implemented by conductive layers and insulating layers.

The display panel 10 includes a display area DA and a peripheral area PA located outside (e.g., in a periphery or outside a footprint of) the display area DA. FIG. 1 shows the display area DA having a rectangular shape. However, one or more embodiments are not limited thereto. The display area DA may have various shapes, for example, a circular shape, an oval shape, a polygonal shape, or a shape of a certain figure.

The display area DA is a portion or area where images are displayed, and may have a plurality of pixels PX arranged therein. Each pixel PX may include a display element, such as an organic light-emitting diode. Each pixel PX may emit, for example, red, green, or blue light. The pixel PX may be connected to a pixel circuit including a thin-film transistor (TFT) and a storage capacitor. The pixel circuit may be connected to a scan line SL configured to transmit a scan signal, a data line DL crossing the scan line SL and configured to transmit a data signal, and a driving voltage line PL configured to supply a driving voltage. The scan line SL may extend in a direction x (hereinafter, a second direction), and the data line DL and the driving voltage line PL may extend in a direction y (hereinafter, a first direction).

The pixel PX may emit light having a luminance corresponding to an electrical signal from the electrically connected pixel circuit. The display area DA may display a certain image through light emitted from the pixel PX. For reference, the pixel PX may be defined as an emission area emitting light having one color among red, green, and blue as described above.

The peripheral area PA is an area where the pixel PX is not arranged, and may be an area where images are not displayed. A power supply line for driving the pixel PX may be located in the peripheral area PA. In addition, pads may be arranged in the peripheral area PA, and a printed circuit board including a driving circuit portion or an integrated circuit device such as a driver IC may be electrically connected to the pads.

For reference, because the display panel 10 includes a substrate 100, the substrate 100 may also be stated to have the display area DA and the peripheral area PA. A detailed description of the substrate 100 is given below.

In addition, a plurality of transistors may be arranged in the display area DA. In the plurality of transistors, depending on the type (N-type or P-type) and/or operation conditions of a transistor, a first terminal of the transistor may be a source electrode or a drain electrode, and a second terminal of the transistor may be an electrode different from the first terminal. For example, when the first terminal is a source electrode, the second terminal may be a drain electrode.

The plurality of transistors may include a driving transistor, a data writing transistor, a compensation transistor, an initialization transistor, and an emission control transistor. The driving transistor may be connected between the driving voltage line PL and an organic light-emitting diode, and the data writing transistor may be connected to the data line DL and the driving transistor and may be configured to perform a switching operation for transmitting a data signal transmitted through the data line DL.

The compensation transistor may be turned on according to a scan signal received through the scan line SL to connect the driving transistor and the organic light-emitting diode to each other, thereby compensating for a threshold voltage of the driving transistor.

The initialization transistor may be turned on according to a scan signal received through the scan line SL to transfer an initialization voltage to a gate electrode of the driving transistor, thereby initializing the gate electrode of the driving transistor. The scan line connected to the initialization transistor may be a separate scan line that is different from the scan line connected to the compensation transistor.

The emission control transistor may be turned on according to an emission control signal received through an emission control line, and as a result, a driving current may flow through the organic light-emitting diode.

The organic light-emitting diode may include a pixel electrode (anode) and an opposite electrode (cathode), and the opposite electrode may receive a second power voltage ELVSS. The organic light-emitting diode may receive a driving current from the driving transistor and emit light, thereby displaying images.

Although an organic light-emitting display device is described below as an example of a display device according to some embodiments, a display device described herein is not limited thereto. According to some embodiments, the display device described herein may be a display device, such as an inorganic light-emitting display (or an inorganic electroluminescent (EL) display) or a quantum dot light-emitting display. For example, an emission layer of a display element included in the display device may include an organic material or an inorganic material. Alternatively, the display device may include an emission layer and quantum dots positioned on a path of light emitted from the emission layer.

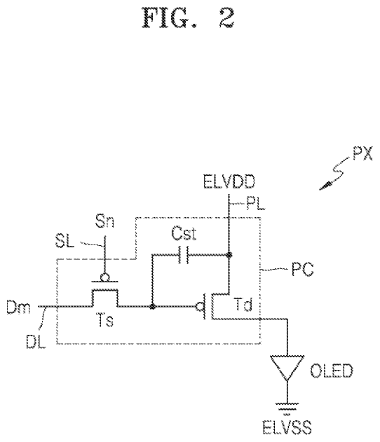

FIG. 2 is an equivalent circuit diagram of the pixel PX included in the display panel 10 of FIG. 1.

As shown in FIG. 2, each pixel PX includes a pixel circuit PC connected to the scan line SL and the data line DL and an organic light-emitting diode OLED connected to the pixel circuit PC. The pixel circuit PC includes a driving thin-film transistor Td, a switching thin-film transistor Ts, and a storage capacitor Cst. The switching thin-film transistor Ts is connected to the scan line SL and the data line DL and is configured to transmit a data signal Dm input through the data line DL to the driving thin-film transistor Td according to a scan signal Sn input through the scan line SL.

The storage capacitor Cst is connected to the switching thin-film transistor Ts and the driving voltage line PL and stores a voltage corresponding to a difference between a voltage received from the switching thin-film transistor Ts and a first power voltage ELVDD supplied to the driving voltage line PL. The second power voltage ELVSS may be a driving voltage having a relatively lower level than the first power voltage ELVDD. The level of a driving voltage supplied to each pixel PX may be a difference between levels of the first power voltage ELVDD and the second power voltage EVLSS.

The driving thin-film transistor Td may be connected to the driving voltage line PL and the storage capacitor Cst and may be configured to control a driving current flowing through the organic light-emitting diode OLED from the driving voltage line PL, in response to a voltage value stored in the storage capacitor Cst. The organic light-emitting diode OLED may emit light having a certain luminance according to the driving current.

Although various elements and components are illustrated in FIG. 2, embodiments according to the present disclosure are not limited thereto. For example, some embodiments may include additional components or fewer components without departing from the spirit and scope of embodiments according to the present disclosure.

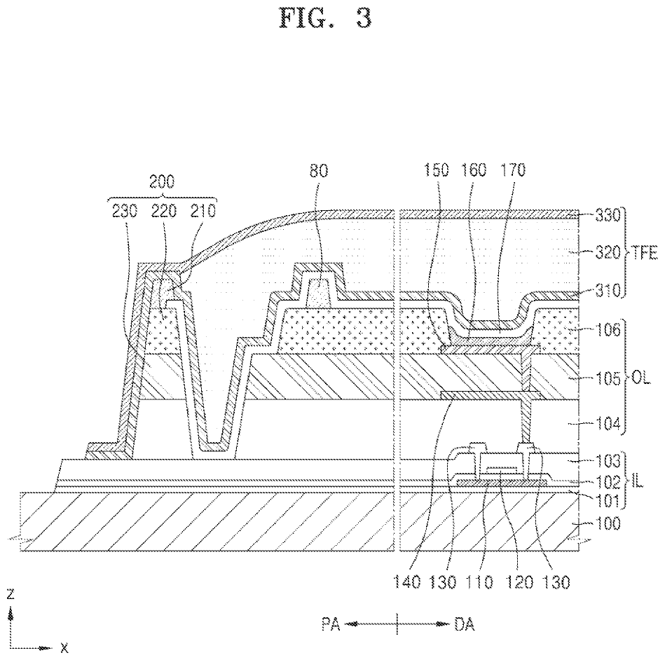

FIG. 3 is a schematic cross-sectional view of a portion of the display panel 10 of FIG. 1.

As described above, the substrate 100 may include areas corresponding to the display area DA and the peripheral area PA outside the display area DA. The substrate 100 may include various materials having flexible or bendable characteristics. For example, the substrate 100 may include glass, metal, or polymer resin. In addition, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be variously modified, for example, to have a multi-layer structure including two layers each including the above polymer resin and a barrier layer between the two layers and including an inorganic material (e.g., silicon oxide, silicon nitride, silicon oxynitride, etc.).

A buffer layer 101 may be on the substrate 100. The buffer layer 101 may serve as a barrier layer and/or a blocking layer for preventing or reducing diffusion of impurity ions, preventing or reducing penetration of moisture, contaminants, or external air, and planarizing a surface. The buffer layer 101 may include silicon oxide, silicon nitride, or silicon oxynitride. In addition, the buffer layer 101 may adjust a rate at which heat is provided during a crystallization process for forming a semiconductor layer 110, thereby uniformly (or relatively uniformly) crystallizing the semiconductor layer 110.

The semiconductor layer 110 may be on the buffer layer 101. The semiconductor layer 110 may be formed of polysilicon and may include a channel region not doped with impurities and a source region and a drain region on both sides of the channel region and formed by doping with impurities. In this regard, impurities vary depending on types of thin-film transistors and may be N-type impurities or P-type impurities.

A gate insulating layer 102 may be on the semiconductor layer 110. The gate insulating layer 102 may be an element for securing insulation between the semiconductor layer 110 and a gate layer 120. The gate insulating layer 102 may include an inorganic material, such as silicon oxide, silicon nitride and/or silicon oxynitride, and may be located between the semiconductor layer 110 and the gate layer 120. In addition, the gate insulating layer 102 may have a formation corresponding to the entire surface of the substrate 100 and may have a structure in which contact holes are formed in previously set portions. Such an insulating layer including an inorganic material may be formed through chemical vapor deposition (CVD) or atomic layer deposition (ALD). The same applies to embodiments described below and modifications thereof.

The gate layer 120 may be on the gate insulating layer 102. The gate layer 120 may be arranged at a position vertically overlapping the semiconductor layer 110 and may include at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), or copper (Cu).

An interlayer insulating layer 103 may be on the gate layer 120. The interlayer insulating layer 103 may cover the gate layer 120. The interlayer insulating layer 103 may be formed of an inorganic material. For example, the interlayer insulating layer 103 may include metal oxide or metal nitride, and more specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). In some embodiments, the interlayer insulating layer 103 may have a dual structure of SiOₓ/SiN_{y} or SiNₓ/SiO_{y}. Thus, as illustrated in FIG. 3, the interlayer insulating layer 103 may be located between the interlayer insulating layer 103 and the gate insulating layer 102.

A first conductive layer 130 may be on the interlayer insulating layer 103. The first conductive layer 130 may serve as an electrode connected to source/drain regions of the semiconductor layer 110 through a through hole in the interlayer insulating layer 103. Thus, the first conductive layer 130 may be formed or deposited on the interlayer insulating layer 103, and one or more vias may be formed through the interlayer insulating layer 103 and extend from the first conductive layer 130 to the source and drain regions of the semiconductor layer 110. The first conductive layer 130 may include one or more metals or conductive materials. For example, the first conductive layer 130 may include one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 130 may include a Ti layer, an Al layer, and/or a Cu layer.

A first organic insulating layer 104 may be on the first conductive layer 130. The first organic insulating layer 104 may be an organic insulating layer that has a substantially flat top surface while covering the top of the first conductive layer 130 and thus serves as a planarization layer. The first organic insulating layer 104 may include, for example, an organic material, such as acryl, benzocyclobutene (BCB), or hexamethyldisiloxane (HMDSO). The first organic insulating layer 104 may be variously modified, for example, to have a single-layer or multi-layer structure.

A second conductive layer 140 may be on the first organic insulating layer 104. The second conductive layer 140 may serve as an electrode connected to source/drain regions of the semiconductor layer 110 through a through hole in the first organic insulating layer 104. The second conductive layer 140 may include one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second conductive layer 140 may include a Ti layer, an Al layer, and/or a Cu layer.

A second organic insulating layer 105 may be on the second conductive layer 140. The second organic insulating layer 105 may be an organic insulating layer that has a substantially flat top surface while covering the top of the second conductive layer 140 and thus serves as a planarization layer. The second organic insulating layer 105 may include, for example, an organic material, such as acryl, BCB, or HMDSO. The second organic insulating layer 105 may be variously modified, for example, to have a single-layer or multi-layer structure.

According to some embodiments, an additional conductive layer and an additional insulating layer may be located between a conductive layer and a pixel electrode and may be applied to various embodiments. In this regard, the additional conductive layer may include the same material as the above-described conductive layer and may have the same layer structure as the above-described conductive layer. The additional insulating layer may include the same material as the above-described organic insulating layer and may have the same layer structure as the above-described organic insulating layer.

A pixel electrode 150 may be on the second organic insulating layer 105. The pixel electrode 150 may be connected to the second conductive layer 140 through a contact hole formed in the second organic insulating layer 105. A display element may be on the pixel electrode 150. The organic light-emitting diode OLED (refer to FIG. 2) may be used as the display element. That is, the organic light-emitting diode OLED (refer to FIG. 2) may be located on, for example, the pixel electrode 150. The pixel electrode 150 may include a transmissive conductive layer formed of transmissive conductive oxide, such as ITO, In₂O₃, or IZO, and a reflective layer formed of metal, such as Al or Ag. For example, the pixel electrode 150 may have a three-layer structure of ITO/Ag/ITO.

A pixel-defining layer 106 may be on the second organic insulating layer 105 and may be arranged so as to cover the edge of the pixel electrode 150. That is, the pixel-defining layer 106 may cover the edge of the pixel electrode 150. The pixel-defining layer 106 may have an opening corresponding to the pixel PX, and the opening may be formed to expose at least a central portion of the pixel electrode 150. The pixel-defining layer 106 may include an organic material, for example, polyimide or HMDSO. In addition, a spacer 80 may be located on the pixel-defining layer 106.

The spacer 80 is shown as being located in the peripheral area PA but may be located in the display area DA. The spacer 80 may prevent or reduce instances of the organic light-emitting diode OLED (refer to FIG. 2) being damaged by the deflection of a mask in a manufacturing process using the mask. The spacer 80 may include an organic insulating material and may have a single-layer or multi-layer structure.

An intermediate layer 160 and an opposite electrode 170 may be located in the opening of the pixel-defining layer 106. The intermediate layer 160 may include a low-molecular weight material or a polymer material, and when the intermediate layer 160 includes a low-molecular weight material, the intermediate layer 160 may include a hole injection layer, a hole transport layer, an emission layer, an electron transport layer and/or an electron injection layer. When the intermediate layer 160 includes a polymer material, the intermediate layer 160 may mostly have a structure including a hole transport layer and an emission layer.

The opposite electrode 170 may include a transmissive conductive layer formed of transmissive conductive oxide, such as ITO, In₂O₃, or IZO. The pixel electrode 150 is used as an anode, and the opposite electrode 170 is used as a cathode. Polarities of the electrodes may be reversed.

A structure of the intermediate layer 160 is not limited to the above description, and the intermediate layer 160 may have various structures. For example, at least one of the layers constituting the intermediate layer 160 may be integrally formed as the opposite electrode 170 does. According to some embodiments, the intermediate layer 160 may include a layer patterned to correspond to each of a plurality of pixel electrodes 150.

The opposite electrode 170 may be arranged in the display area DA and may be arranged across the entire surface of the display area DA. That is, the opposite electrode 170 may be integrally formed to cover a plurality of pixels. The opposite electrode 170 may be in electrical contact with a common power supply line arranged in the peripheral area PA. According to some embodiments, the opposite electrode 170 may extend to a blocking wall 200. A thin film encapsulation layer TFE may cover the entire display area DA and may extend toward the peripheral area PA to cover at least a portion of the peripheral area PA.

The thin film encapsulation layer TFE may extend to the outside of the common power supply line. The thin film encapsulation layer TFE may include a first inorganic encapsulation layer 310, a second inorganic encapsulation layer 330, and an organic encapsulation layer 320 located therebetween. The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride.

The first inorganic encapsulation layer 310 and the second inorganic encapsulation layer 330 may have a single-layer or multi-layer structure including the above-described material. The first inorganic encapsulation layer 310 and the second inorganic encapsulation layer 330 may include the same material as each other or may include different materials from each other. Thicknesses of the first inorganic encapsulation layer 310 and the second inorganic encapsulation layer 330 may be different from each other. The first inorganic encapsulation layer 310 may be thicker than the second inorganic encapsulation layer 330. Alternatively, the second inorganic encapsulation layer 330 may be thicker than the first inorganic encapsulation layer 310, or thicknesses of the first inorganic encapsulation layer 310 and the second inorganic encapsulation layer 330 may be the same as each other.

The organic encapsulation layer 320 may include a monomer-based material or a polymer-based material. Examples of the polymer-based material may include acryl-based resin, epoxy-based resin, polyimide, and polyethylene. According to some embodiments, the organic encapsulation layer 320 may include acrylate.

The blocking wall 200 may be located in the peripheral area PA of the substrate 100. According to some embodiments, the blocking wall 200 may include a portion of the first organic insulating layer 104, a portion 230 of the second organic insulating layer 105, a portion 220 of the pixel-defining layer 106, and a portion 210 of the spacer 80, but one or more embodiments are not limited thereto.

In some cases, the blocking wall 200 may be formed of only the portion 230 of the second organic insulating layer 105 or the portion 220 of the pixel-defining layer 106. The blocking wall 200 may surround the display area DA and may prevent or reduce instances of the organic encapsulation layer 320 of the thin film encapsulation layer TFE overflowing to the outside of the substrate 100. Accordingly, the organic encapsulation layer 320 may be in contact with an inner surface of the blocking wall 200 facing the display area DA. In this regard, it may be understood that the description that the organic encapsulation layer 320 is in contact with the inner surface of the blocking wall 200 means that the first inorganic encapsulation layer 310 is between the organic encapsulation layer 320 and the blocking wall 200 and the organic encapsulation layer 320 is in contact with the first inorganic encapsulation layer 310.

The first inorganic encapsulation layer 310 and the second inorganic encapsulation layer 330 may be located over the blocking wall 200 and may extend toward an edge of the substrate 100. In some cases, the blocking wall 200 may include a plurality of blocking walls 200.

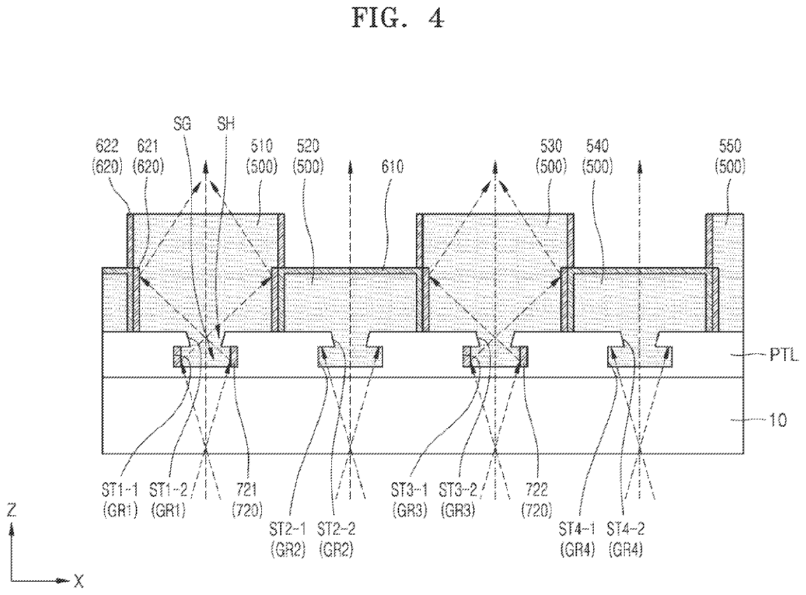

FIG. 4 is a schematic cross-sectional view of a display device according to some embodiments.

As shown in FIG. 4, the display device may include the display panel 10, a protection layer PTL located on the display panel 10, and a plurality of transparent partition walls 500 located on the protection layer PTL. A description of the display panel 10 is the same as or overlaps that given above with reference to FIGS. 1 to 3 and thus may be omitted.

The protection layer PTL may be located on the display panel 10 and may include a plurality of grooves, for example, first to fourth grooves GR1, GR2, GR3, and GR4 each having an anchor shape. Each of the plurality of grooves, for example, the first to fourth grooves GR1, GR2, GR3, and GR4 may be formed in a direction from a top surface of the protection layer PTL toward the display panel 10. The number of grooves GR1, GR2, GR3, and GR4 is not limited to the number of grooves shown.

The protection layer PTL may be an inorganic layer. The protection layer PTL may include one or more inorganic materials among aluminum oxide, titanium oxide, tantalum oxide, hafnium oxide, zinc oxide, silicon oxide, silicon nitride, and silicon oxynitride.

Each of the plurality of grooves, for example, the first to fourth grooves GR1, GR2, GR3, and GR4 may include a sub-hole SH extending toward the display panel 10 as far as a certain distance from the top surface of the protection layer PTL and a sub-groove SG extending toward the display panel 10 as far as a certain distance from the bottom of the sub-hole SH. The sub-hole SH and the sub-groove SG may both constitute an anchor shape. When viewed in a direction perpendicular or normal with respect to the display panel 10 or a display surface of the display panel 10 (e.g., in a plan view), a width of the sub-hole SH in the x-axis direction may be less than that of the sub-groove SG in the x-axis direction.

In other words, when viewed in a direction perpendicular to the display panel 10 (e.g., in a plan view), each of the plurality of grooves, for example, the first to fourth grooves GR1, GR2, GR3, and GR4 may have a different width for each location.

The plurality of grooves, for example, the first to fourth grooves GR1, GR2, GR3, and GR4 may include at least a first groove GR1. Accordingly, in some cases, the plurality of grooves, for example, the first to fourth grooves GR1, GR2, GR3, and GR4 may further include a second groove GR2 and a third groove GR3. The plurality of grooves, for example, the first to fourth grooves GR1, GR2, GR3, and GR4 may further include other grooves.

The second groove GR2 may be spaced apart from the first groove GR1 in the x-axis direction. The third groove GR3 may be spaced apart from the first groove GR1 and the second groove GR2 in the x-axis direction, and the second groove GR2 may be arranged between the first groove GR1 and the third groove GR3. The third groove GR3 may be spaced apart from the second groove GR2 in a direction opposite to a direction toward the first groove GR1.

In the present description, the x-axis direction may refer to a width direction of the display panel 10, and the y-axis direction may refer to a length direction of the display panel 10.

According to some embodiments, the plurality of grooves, for example, the first to fourth grooves GR1, GR2, GR3, and GR4 may extend long in the length direction of the display panel 10 and may be parallel to one another in the length direction of the display panel 10.

A reflective functional layer 720, such as a 1-1 layer 721, a 1-2 layer 722, etc., may be located on portions of inner side surfaces of at least some of the plurality of grooves, for example, the first to fourth grooves GR1, GR2, GR3, and GR4. The reflective functional layer 720, such as the 1-1 layer 721, the 1-2 layer 722, etc., may perform the function for absorbing and/or reflecting light beams generated from the display panel 10. The reflective functional layer 720 may be a concept including the 1-1 layer 721, the 1-2 layer 722, and the like described below.

As an example, the first groove GR1 may correspond to a first transparent partition wall 510 described below. The 1-1 layer 721 may be located on at least a portion of inner side surfaces, for example, a 1-1 sub-inner side surface ST1-1 and a 1-2 sub-inner side surface ST1-2 of the first groove GR1. That is, the 1-1 layer 721 may be arranged along at least a portion of the inner side surfaces, for example, the 1-1 sub-inner side surface ST1-1 and the 1-2 sub-inner side surface ST1-2 of the first groove GR1. The 1-1 layer 721 may perform the function for absorbing and/or reflecting light beams generated from the display panel 10.

As an example, the third groove GR3 may correspond to a third transparent partition wall 530 described below. The 1-2 layer 722 may be located on at least a portion of inner side surfaces, for example, a 3-1 sub-inner side surface ST3-1 and a 3-2 sub-inner side surface ST3-2 of the third groove GR3. That is, the 1-2 layer 722 may be arranged along at least a portion of the inner side surfaces, for example, a 3-1 sub-inner side surface ST3-1 and a 3-2 sub-inner side surface ST3-2 of the third groove GR3. The 1-2 layer 722 may perform the function for absorbing and/or reflecting light beams generated from the display panel 10.

The plurality of transparent partition walls 500 may be located on the protection layer PTL. Each of the plurality of transparent partition walls 500 may include polyamide (PI). That is, the plurality of transparent partition walls 500 may include a transparent organic material.

The plurality of transparent partition walls 500 may include at least the first transparent partition wall 510. Accordingly, in some cases, the plurality of transparent partition walls 500 may further include a second transparent partition wall 520 and the third transparent partition wall 530. The plurality of transparent partition walls 500 may further include other transparent partition walls.

The second transparent partition wall 520 may be spaced apart from the first transparent partition wall 510 in the x-axis direction. The third transparent partition wall 530 may be spaced apart from the first transparent partition wall 510 and the second transparent partition wall 520, and the second transparent partition wall 520 may be arranged between the first transparent partition wall 510 and the third transparent partition wall 530.

The plurality of transparent partition walls 500 may correspond to the plurality of grooves, for example, the first to fourth grooves GR1, GR2, GR3, and GR4, respectively. The plurality of transparent partition walls 500 may be arranged along the plurality of grooves, for example, the first to fourth grooves GR1, GR2, GR3, and GR4, respectively. Each of the plurality of transparent partition walls 500 may fill the inside of a corresponding groove.

As an example, the first transparent partition wall 510 may be arranged along the first groove GR1, and a portion of the first transparent partition wall 510 may fill the inside of the first groove GR1. That is, the first transparent partition wall 510 may be formed while filling the inside of the first groove GR1.

Such a feature may also apply to the second transparent partition wall 520, the third transparent partition wall 530, and the like in the same way. That is, the second transparent partition wall 520 may be arranged along the second groove GR2, and a portion of the second transparent partition wall 520 may fill the inside of the second groove GR2. The second transparent partition wall 520 may be formed while filling the inside of the second groove GR2. The third transparent partition wall 530 may be arranged along the third groove GR3, and a portion of the third transparent partition wall 530 may fill the inside of the third groove GR3. The third transparent partition wall 530 may be formed while filling the inside of the third groove GR3.

A distance between a top surface of the third transparent partition wall 530 and a top surface of the display panel 10 may be greater than a distance between a top surface of the second transparent partition wall 520 and the top surface of the display panel 10.

When viewed in a direction perpendicular to the display panel 10 (e.g., in a plan view), the third transparent partition wall 530 may be symmetrical to the first transparent partition wall 510 with respect to the second transparent partition wall 520. That is, each of odd-numbered transparent partition walls and each of even-numbered transparent partition walls may be alternately arranged, and adjacent transparent partition walls among the odd-numbered transparent partition walls may be symmetrical to each other with respect to an even-numbered transparent partition wall arranged between the adjacent transparent partition walls.

The above features of the first transparent partition wall 510 to the third transparent partition wall 530 may also apply to a fourth groove GR4, a fifth groove, a fourth transparent partition wall 540, a fifth transparent partition wall 550, and the like.

For example, as described above, the anchor shape of each of the plurality of grooves, for example, the first to fourth grooves GR1, GR2, GR3, and GR4 may be formed using an undercut in which an inner side surface at a certain depth or greater among inner side surfaces of each of the plurality of grooves, for example, the first to fourth grooves GR1, GR2, GR3, and GR4 is excessively etched. Accordingly, a portion of each of the plurality of transparent partition walls 500 may fill the anchor shape of each of the plurality of grooves, for example, the first to fourth grooves GR1, GR2, GR3, and GR4 and thus may serve as an anchor. As a result, adhesion strength between the plurality of transparent partition walls 500 and the protection layer PTL may be greatly increased. Accordingly, a defect in which at least some of the plurality of transparent partition walls 500 are separated from the protection layer PTL may be reduced.

In this regard, a distance between the top surface of the second transparent partition wall 520 and the top surface of the display panel 10 may be less than a distance between a top surface of the first transparent partition wall 510 and the top surface of the display panel 10. That is, a height of the first transparent partition wall 510 may be greater than a height of the second transparent partition wall 520.

An outer side surface and the top surface of the second transparent partition wall 520 may be covered by an inorganic layer 610. The inorganic layer 610 may include a transparent material and may include one or more inorganic materials among aluminum oxide, titanium oxide, tantalum oxide, hafnium oxide, zinc oxide, silicon oxide, silicon nitride, and silicon oxynitride. Accordingly, in the present description, the outer side surface of the second transparent partition wall 520 may refer to an outer side surface of the inorganic layer 610 arranged along the outer side surface of the second transparent partition wall 520.

According to some embodiments, because the plurality of transparent partition walls 500 correspond to the plurality of grooves, for example, the first to fourth GR1, GR2, GR3, and GR4, respectively, each of the plurality of transparent partition walls 500 may extend long in the length direction of the display panel 10, and the plurality of transparent partition walls 500 may be parallel to one another in the length direction of the display panel 10.

As shown in FIG. 4, a height of the first transparent partition wall 510 and a height of the third transparent partition wall 530 may be the same as each other. That is, a height of the third transparent partition wall 530 may be greater than a height of the second transparent partition wall 520. As such, transparent partition walls having different heights may be arranged adjacent to each other, and thus, side light may be more efficiently removed and only vertical light may be emitted.

As such, each of the odd-numbered transparent partition walls (e.g., the first transparent partition wall 510, the third transparent partition wall 530, etc.) having the same feature as the first transparent partition wall 510 and each of the even-numbered transparent partition walls (e.g., the second transparent partition wall 520, the fourth transparent partition wall 540, etc.) having the same feature as the second transparent partition wall 520 may be alternately arranged.

A 2-1 layer 622, a 2-2 layer 621, and the like including the same material as the reflective functional layer 720 described above may be located on an outer side surface of each of the plurality of transparent partition walls 500. The 2-1 layer 622, the 2-2 layer 621, and the like may perform the function for absorbing and/or reflecting light beams generated from the display panel 10. The 2-1 layer 622, the 2-2 layer 621, and the like may include the same material as the 1-1 layer 721, the 1-2 layer 722, and the like described above.

As an example, the 2-1 layer 622 may be located on an outer side surface of the first transparent partition wall 510. That is, the 2-1 layer 622 may be arranged along at least a portion of the outer side surface of the first transparent partition wall 510. The 2-1 layer 622 may perform the function for absorbing and/or reflecting light beams generated from the display panel 10.

The 2-2 layer 621 may be arranged between the outer side surface of the first transparent partition wall 510 and the outer side surface of the second transparent partition wall 520. The 2-2 layer 621 may be formed separately from the 2-1 layer 622. As a result, the 2-2 layer 621 may be disconnected from or only partially in contact with the 2-1 layer 622. The 2-2 layer 621 may include the same material as the 2-1 layer 622. The 2-1 layer 622 and the 2-2 layer 621 may include the same material as the 1-1 layer 721. The same material may be a light-absorbing material and/or a reflective material.

As an example, the reflective functional layer 720 may include a light-absorbing material including molybdenum (Mo). Alternatively, the reflective functional layer 720 may include at least one of molybdenum (Mo), manganese (Mn), or magnesium (Mg), and these materials may be the metal having a light absorption coefficient. In addition, the reflective functional layer 720 may have a three-layer structure. That is, the reflective functional layer 720 may have a three-layer structure of a first material layer, a second material layer, and a first material layer.

As an example, the first material layer may include molybdenum-tantalum oxide (MoTaOₓ, MTO). That is, the first material layer may include a material obtained by oxidizing molybdenum (Mo) and tantalum (Ta). Although molybdenum (Mo) is a representative light-absorbing material, the light absorbency of molybdenum (Mo) may decrease as the content of tantalum (Ta) increases. In other words, even when molybdenum-tantalum oxide (MoTaOₓ, MTO), which is a light-absorbing material, is included in the first material layer, part of irradiated light may be reflected.

The second material layer may include molybdenum (Mo). Accordingly, one side and the other side of the second material layer may be covered by the first material layer. Accordingly, when the reflective functional layer 720 is irradiated with light, part of the light may be absorbed by the first material layer, and the rest of the light may be reflected by the first material layer.

In some cases, the reflective functional layer 720 (or the 1-1 layer 721) may include metal, such as Al or Ag. Metal, such as Al or Ag, may have a higher reflectance than molybdenum (Mo) or molybdenum-tantalum oxide (MoTaOₓ, MTO).

As shown in FIG. 4, the inner side surfaces, for example, the 1-1 sub-inner side surface ST1-1 and the 1-2 sub-inner side surface ST1-2 of the first groove GR1 may include a 1-1 sub-inner side surface ST1-2 extending from the top surface of the protection layer PTL in a direction toward the display panel 10 and having a first width when viewed in a direction perpendicular to the display panel 10 (e.g., in a plan view). In addition, the inner side surfaces, for example, the 1-1 sub-inner side surface ST1-1 and the 1-2 sub-inner side surface ST1-2 of the first groove GR1 may further include a 1-2 sub-inner side surface ST1-1 extending from the bottom of the 1-1 sub-inner side surface ST1-2 in a direction toward the display panel 10 and having a second width that is greater than the first width when viewed in a direction perpendicular to the display panel 10 (e.g., in a plan view).

In this regard, the first width and the second width may refer to a width in the x-axis direction when viewed in a direction perpendicular to the display panel 10 (e.g., in a plan view). According to some embodiments, the first groove GR1 and the second groove GR2 may respectively have a first length and a second length in the y-axis direction.

The 1-1 layer 721 may be arranged along the 1-2 sub-inner side surface ST1-1. That is, the 1-1 layer 721 may not be arranged along the 1-1 sub-inner side surface ST1-2. The 1-1 layer 721 may be in contact with the 1-2 sub-inner side surface ST1-1 and may not be in contact with the 1-1 sub-inner side surface ST1-2.

The plurality of transparent partition walls 500 shown in FIG. 4, etc. are shown as having a vertical shape with respect to the top surface of the display panel 10 but are shown in the vertical shape for convenience, and side surfaces of the plurality of transparent partition walls 500 may have various inclinations relative to the top surface of the display panel 10. One example thereof is a display device according to some embodiments as described below.

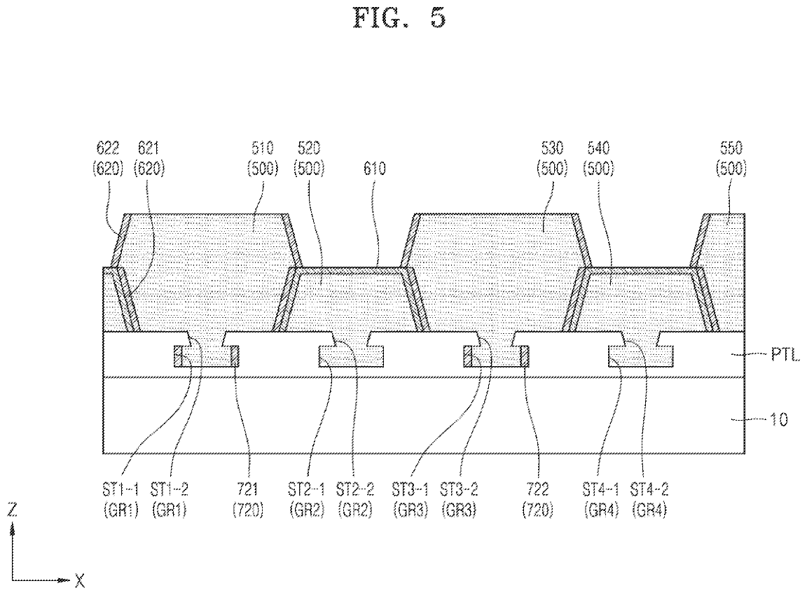

FIG. 5 is a schematic cross-sectional view of a display device according to some embodiments. A description of FIG. 5 that is the same as or overlaps the above description may be omitted.

As shown in FIG. 5, the side surface of each of the plurality of transparent partition walls 500 may have an inclination relative to a top surface of the display panel 10. More specifically, when viewed in a direction perpendicular to the display panel 10 (e.g., in a plan view), an area of a top surface of the second transparent partition wall 520 may be less than an area of a bottom surface of the second transparent partition wall 520. In this regard, the bottom surface of the second transparent partition wall 520 may refer to a cross-section of the second transparent partition wall 520 taken along a top surface of the protection layer PTL. In addition, when viewed in a direction perpendicular to the display panel 10 (e.g., in a plan view), the top surface of the second transparent partition wall 520 may be included in the bottom surface of the second transparent partition wall 520.

As shown in FIG. 5, when viewed in a direction perpendicular to the display panel 10 (e.g., in a plan view), an area of a top surface of the first transparent partition wall 510 may be less than an area of a central surface of the first transparent partition wall 510. In this regard, the central surface of the first transparent partition wall 510 may refer to a cross-section of the first transparent partition wall 510 taken along an imaginary surface obtained by extending the top surface of the second transparent partition wall 520. In addition, when viewed in a direction perpendicular to the display panel 10 (e.g., in a plan view), the top surface of the first transparent partition wall 510 may be included in the central surface of the first transparent partition wall 510.

When viewed in a direction perpendicular to the display panel 10 (e.g., in a plan view), an area of a bottom surface of the first transparent partition wall 510 may be less than an area of the central surface of the first transparent partition wall 510. In this regard, the bottom surface of the first transparent partition wall 510 may refer to a cross-section of the first transparent partition wall 510 taken along the top surface of the protection layer PTL. In addition, when viewed in a direction perpendicular to the display panel 10 (e.g., in a plan view), the bottom surface of the first transparent partition wall 510 may be included in the central surface of the first transparent partition wall 510.

The feature of the first transparent partition wall 510 described above may be the same as the feature of odd-numbered transparent partition walls. Likewise, the feature of the second transparent partition wall 520 described above may be the same as the feature of even-numbered transparent partition walls.

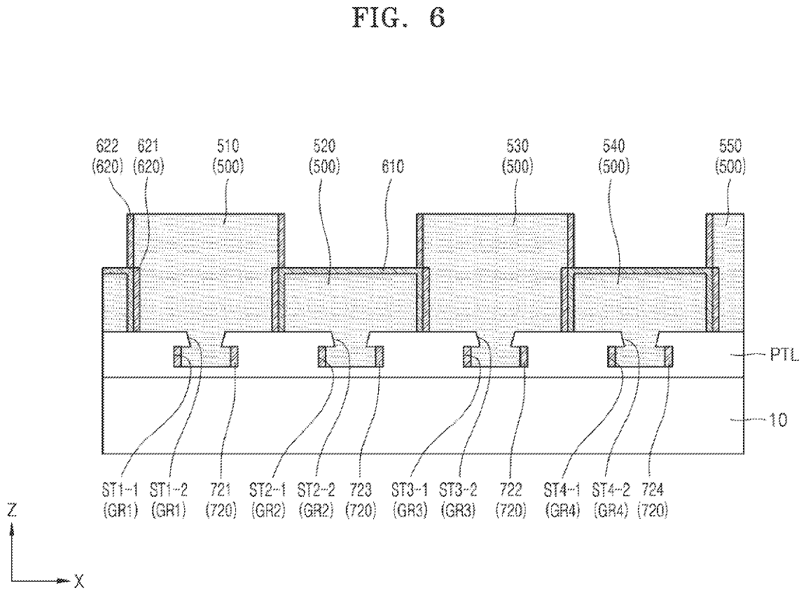

FIG. 6 is a schematic cross-sectional view of a display device according to some embodiments.

As shown in FIG. 6, inner side surfaces, for example, a 2-1 sub-inner side surface ST2-1 and a 2-2 sub-inner side surface ST2-2 of the second groove GR2 may include a 2-1 sub-inner side surface ST2-2 extending from a top surface of the protection layer PTL in a direction toward the display panel 10 and having a 1′st width when viewed in a direction perpendicular to the display panel 10 (e.g., in a plan view). In addition, the inner side surfaces, for example, the 2-1 sub-inner side surface ST2-1 and the 2-2 sub-inner side surface ST2-2 of the second groove GR2 may further include a 2-2 sub-inner side surface ST2-1 extending from the bottom of the 2-1 sub-inner side surface ST2-2 in a direction toward the display panel 10 and having a 2′nd width greater than the 1′st width when viewed in a direction perpendicular to the display panel 10 (e.g., in a plan view).

In this regard, the 1′st width and the 2′nd width may refer to a width in the x-axis direction when viewed in a direction perpendicular to the display panel 10 (e.g., in a plan view).

A 1-3 layer 723 may be arranged along the 2-2 sub-inner side surface ST2-1. That is, the 1-3 layer 723 may not be arranged along the 2-1 sub-inner side surface ST2-2. The 1-3 layer 723 may be in contact with the 2-2 sub-inner side surface ST2-1 and may not be in contact with the 2-1 sub-inner side surface ST2-2.

Likewise, inner side surfaces, for example, a 4-1 sub-inner side surface ST4-1 and a 4-2 sub-inner side surface ST4-2 of the fourth groove GR4 may include a 4-1 sub-inner side surface ST4-2 extending from the top surface of the protection layer PTL in a direction toward the display panel 10 and having the 1′st width when viewed in a direction perpendicular to the display panel 10 (e.g., in a plan view). In addition, the inner side surfaces, for example, the 4-1 sub-inner side surface ST4-1 and the 4-2 sub-inner side surface ST4-2 of the fourth groove GR4 may further include a 4-2 sub-inner side surface ST4-1 extending from the bottom of the 4-1 sub-inner side surface ST4-2 in a direction toward the display panel 10 and having the 2′nd width greater than the 1′st width when viewed in a direction perpendicular to the display panel 10 (e.g., in a plan view).

In this regard, the 1′st width and the 2′nd width may refer to a width in the x-axis direction when viewed in a direction perpendicular to the display panel 10 (e.g., in a plan view).

A 1-4 layer 724 may be arranged along the 4-2 sub-inner side surface ST4-1. That is, the 1-4 layer 724 may not be arranged along the 4-1 sub-inner side surface ST4-2. The 1-4 layer 724 may be in contact with the 4-2 sub-inner side surface ST4-1 and may not be in contact with the 4-1 sub-inner side surface ST4-2.

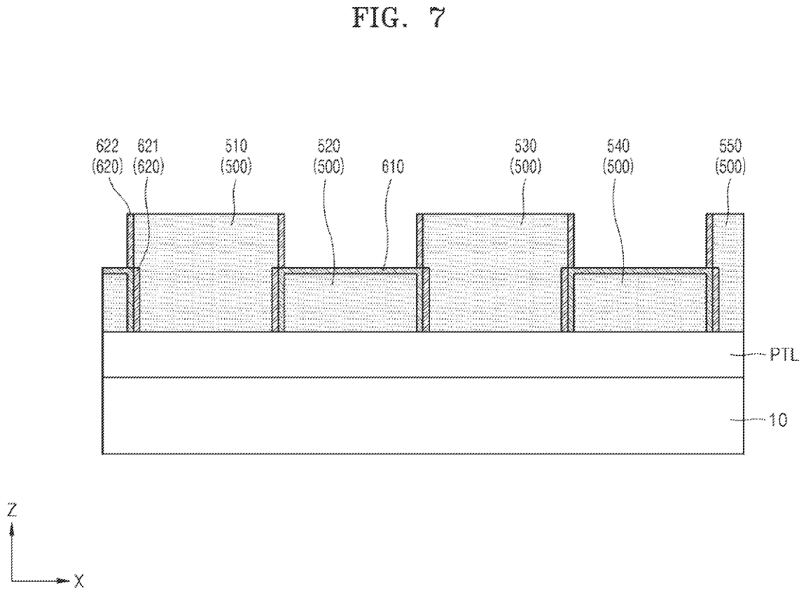

FIG. 7 is a schematic cross-sectional view of a display device according to a comparative example.

As shown in FIG. 7, the protection layer PTL of the display device according to the comparative example may include no groove. The protection layer PTL may include an inorganic material, and the plurality of transparent partition walls 500 may include an organic material, such as polyamide (PI). Adhesion between the layer including an inorganic material and the layer including an organic material is relatively weak, and further, there may be a problem in which odd-numbered transparent partition walls (e.g., the first transparent partition wall 510, the third transparent partition wall 530, etc.) and even-numbered transparent partition walls (e.g., the second transparent partition wall 520, the fourth transparent partition wall 540, etc.) are separately formed and thus easily separated from each other.

Hereinafter, a method of manufacturing a display device (hereinafter, a manufacturing method) according to some embodiments is described in more detail based on the above descriptions. For reference, a description of the manufacturing method that is the same as or overlaps a description of the above-described display device may be omitted.

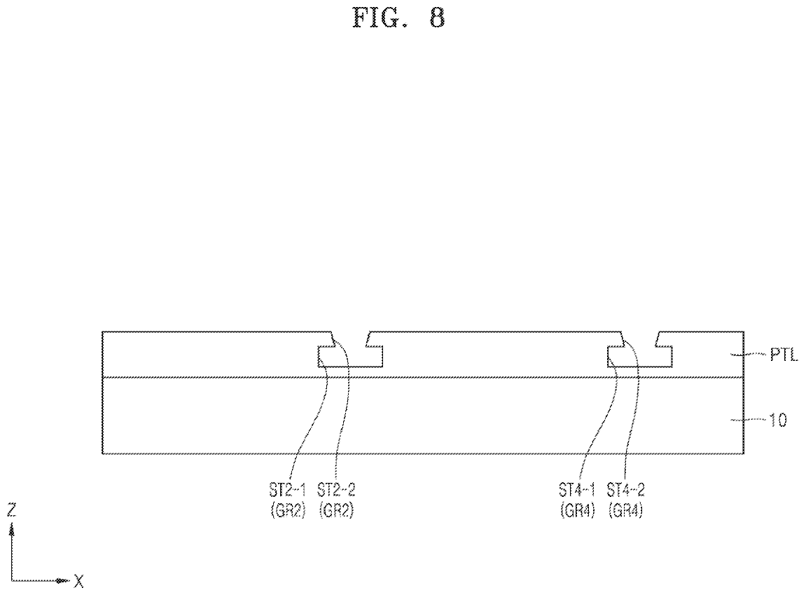

FIGS. 8 to 18 are cross-sectional views sequentially showing a method of manufacturing the display device according to some embodiments. Although the drawings are shown based on some embodiments, the same manufacturing method may also apply to other embodiments.

As shown in FIG. 8, the manufacturing method according to some embodiments may include an operation of preparing the display panel 10 and the protection layer PTL located on the display panel 10. Descriptions of the display panel 10 and the protection layer PTL are the same as or overlap the above descriptions and thus may be omitted.

The manufacturing method according to some embodiments may include an operation of forming a first plurality of grooves, for example, the second groove GR2 and the fourth groove GR4 in the prepared protection layer PTL. The first plurality of grooves, for example, the second groove GR2 and the fourth groove GR4 may include the second groove GR2 described above and may refer to the even-numbered grooves described above. The first plurality of grooves, for example, the second groove GR2 and the fourth groove GR4 may each have an anchor shape.

The operation of forming the first plurality of grooves, for example, the second groove GR2 and the fourth groove GR4 in the protection layer PTL may include a photolithography process using a mask and an etching process. In this regard, negative photoresist or positive photoresist may be used in the photolithography process.

The mask may be divided into a transmission area for transmitting light and a blocking area for blocking light transmission according to light transmittance. However, in some cases, a halftone mask, etc. may be used, and the type of mask may be variously changed, and the scope of embodiments according to the present disclosure is not limited by the type of mask.

A patterning process is as follows. First, the protection layer PTL may be coated with negative photoresist, and then, the photoresist may be exposed to light through a mask and be developed. A first portion of the photoresist corresponding to a transmission area of the mask remains thick without being removed, and a second portion of the photoresist corresponding to a blocking area of the mask is not exposed to light and thus is completely removed. When the protection layer PTL is etched to a photoresist pattern formed as such, a first plurality of grooves having a pattern having a previously set shape in a region corresponding to the first portion may be formed.

An etching process is as follows. The etching process may be divided into an anisotropic etching process and an isotropic etching process. The anisotropic etching process may generally refer to a dry etching process. The isotropic etching process may generally refer to a wet etching process.

The anisotropic etching process may be applied to the operation of forming the first plurality of grooves, for example, the second groove GR2 and the fourth groove GR4 in the protection layer PTL, and after a first etching process is performed to a previously determined depth, a second etching process may be performed by applying the isotropic etching process to a previously determined depth to form an anchor shape.

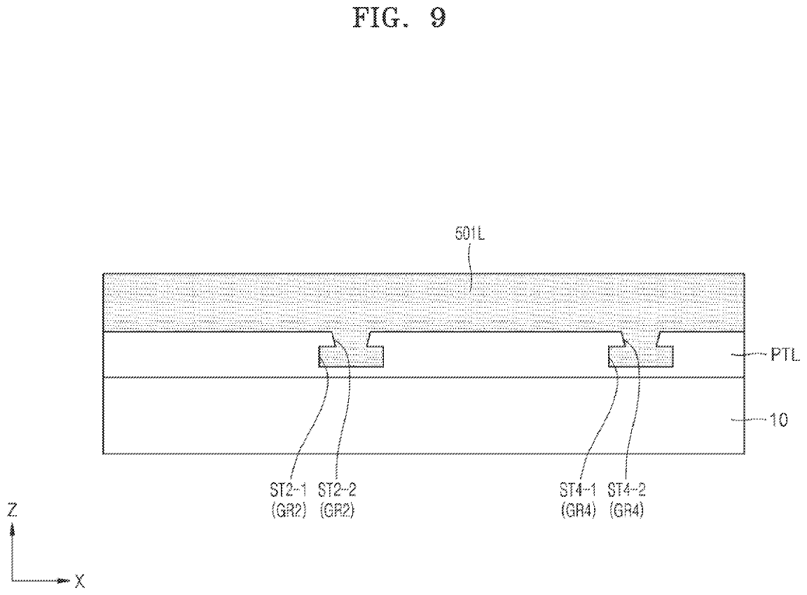

As shown in FIG. 9, the manufacturing method according to some embodiments may further include an operation of forming a first organic material layer 501L on the protection layer PTL after forming the first plurality of grooves, for example, the second groove GR2 and the fourth groove GR4. The first organic material layer 501L may include a transparent organic material, such as polyamide (PI). The first organic material layer 501L may be formed on the protection layer PTL while filling the first plurality of grooves, for example, the second groove GR2 and the fourth groove GR4.

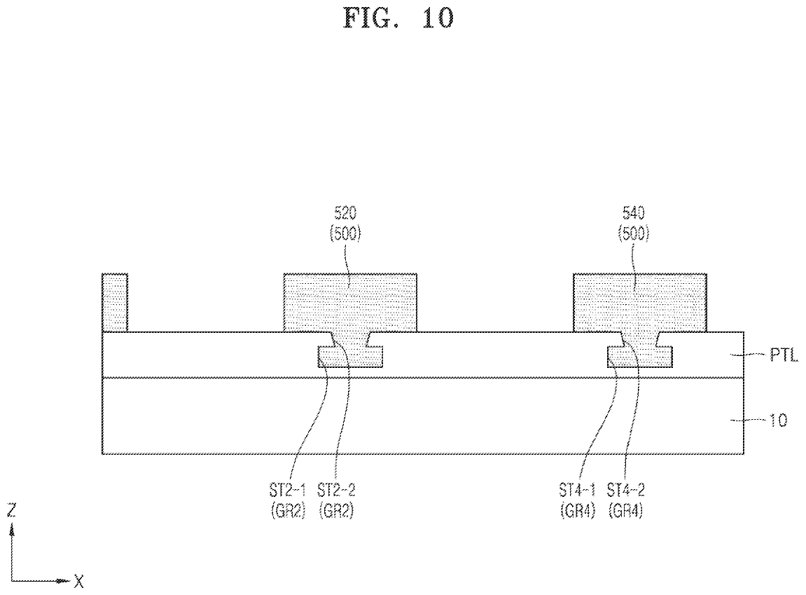

As shown in FIG. 10, the manufacturing method according to some embodiments may further include an operation of forming a first plurality of transparent partition walls, for example, the second transparent partition wall 520 and the fourth transparent partition wall 540 by applying an etching process to the first organic material layer 501L, after forming the first organic material layer 501L. In this regard, the first plurality of transparent partition walls, for example, the second transparent partition wall 520 and the fourth transparent partition wall 540 may refer to the even-numbered transparent partition walls described above.

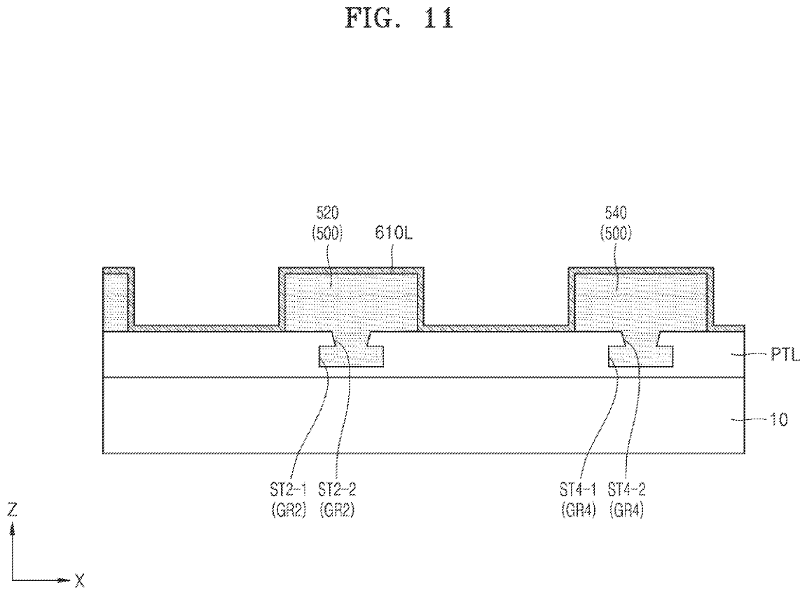

As shown in FIG. 11, the manufacturing method according to some embodiments may further include an operation of forming the inorganic layer 610L covering a top surface of the protection layer PTL exposed between the first plurality of transparent partition walls, for example, the second transparent partition wall 520 and the fourth transparent partition wall 540 and outer side surfaces and top surfaces of the first plurality of transparent partition walls, for example, the second transparent partition wall 520 and the fourth transparent partition wall 540, after forming the first plurality of transparent partition walls, for example, the second transparent partition wall 520 and the fourth transparent partition wall 540.

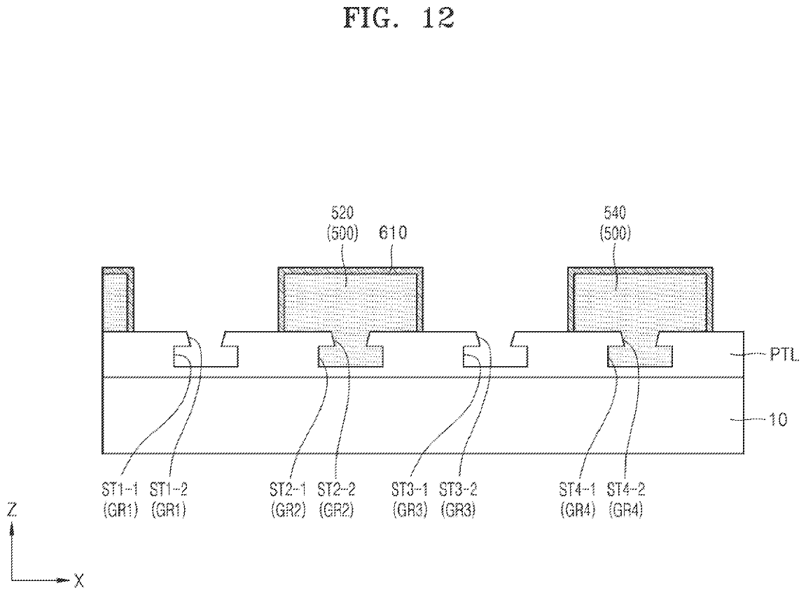

As shown in FIG. 12, the manufacturing method according to some embodiments may further include an operation of removing a portion of the inorganic layer 610 by applying an etching process to the inorganic layer 610, after forming the inorganic layer 610. In this regard, a portion of the inorganic layer 610 may refer to a portion located on the top surface of the protection layer PTL exposed between the first plurality of transparent partition walls, for example, the second transparent partition wall 520 and the fourth transparent partition wall 540. That is, only a portion of the inorganic layer 610 covering an outer side surface and a top surface of each of the first plurality of transparent partition walls, for example, the second transparent partition wall 520 and the fourth transparent partition wall 540 may remain, and the other portion may be removed.

As shown in FIG. 12, the manufacturing method according to some embodiments may further include an operation of forming a second plurality of grooves, for example, the first groove GR1 and the third groove GR3 in the top surface of the protection layer PTL exposed between remaining inorganic layers 610, after removing a portion of the inorganic layer 610.

In this regard, the operation of forming the second plurality of grooves, for example, the first groove GR1 and the third groove GR3 may be the same as the operation of forming the first plurality of grooves, for example, the second groove GR2 and the fourth groove GR4 described above. As a result, the second plurality of grooves, for example, the first groove GR1 and the third groove GR3 may have an anchor shape as the first plurality of grooves, for example, the second groove GR2 and the fourth groove GR4 do. In addition, the second plurality of grooves, for example, the first groove GR1 and the third groove GR3 may refer to the odd-numbered grooves described above.

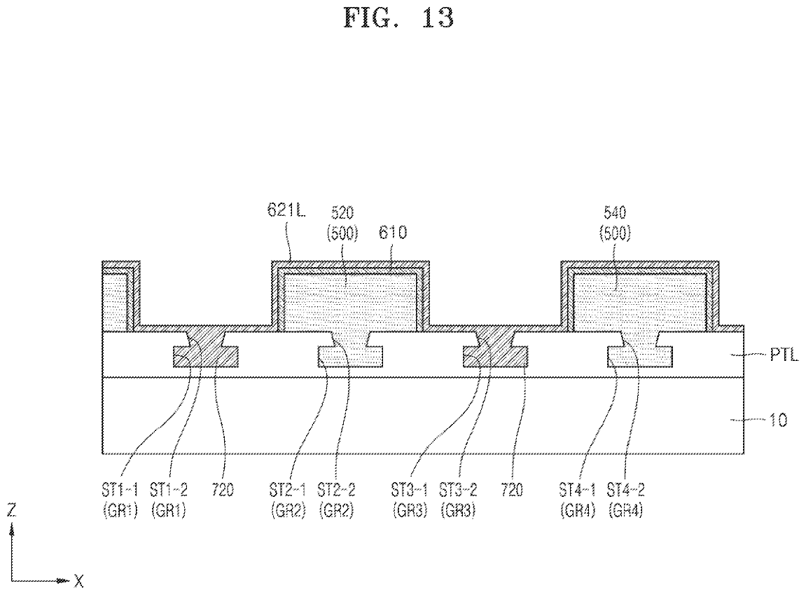

As shown in FIG. 13, the manufacturing method according to some embodiments may further include an operation of forming a first reflective functional layer 621L covering the remaining inorganic layers 610 while filling the second plurality of grooves, for example, the first groove GR1 and the third groove GR3 and covering the top surface of the protection layer PTL exposed between the remaining inorganic layers 610, after forming the second plurality of grooves, for example, the first groove GR1 and the third groove GR3. In this regard, the first reflective functional layer 621L may fill the second plurality of grooves, for example, the first groove GR1 and the third groove GR3.

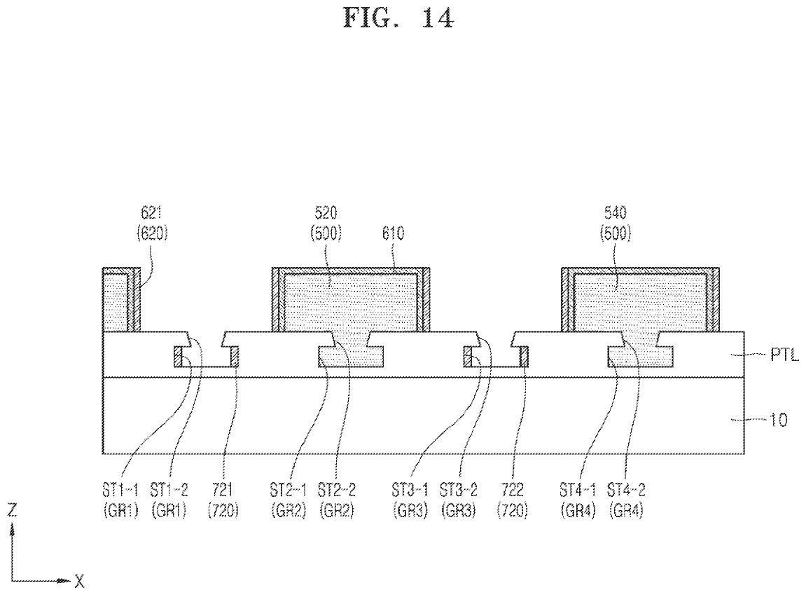

As shown in FIG. 14, the manufacturing method according to some embodiments may further include an operation of forming the 1-1 layer 721, the 1-2 layer 722, and the 2-2 layer 621 by removing a portion of the first reflective functional layer 621L, after forming the first reflective functional layer 621L. During the operation of removing a portion of the first reflective functional layer 621L, an anisotropic etching process and/or an isotropic etching process may be performed to remove a portion of the first reflective functional layer 621L and form the 1-1 layer 721, the 1-2 layer 722, and the 2-2 layer 621.

As an example, when an isotropic etching process is performed after an anisotropic etching process is performed, the 1-1 layer 721 and the 1-2 layer 722 may be formed along portions of inner side surfaces of the odd-numbered grooves. As a result, the 1-1 layer 721 may be arranged along the 1-2 sub-inner side surface ST1-1, and the 1-2 layer 722 may be arranged along a 3-2 sub-inner side surface ST3-1.

In addition, the first reflective functional layer 621L may remain along outer side surfaces of the first plurality of transparent partition walls, for example, the second transparent partition wall 520 and the fourth transparent partition wall 540. That is, the first reflective functional layer 621L may be arranged along outer side surfaces of the first plurality of transparent partition walls, for example, the second transparent partition wall 520 and the fourth transparent partition wall 540, and the 2-2 layer 621 may be formed. As a result, the 2-2 layer 621 may be arranged along the outer side surface of each of the first plurality of transparent partition walls, for example, the second transparent partition wall 520 and the fourth transparent partition wall 540, and more specifically, may be arranged along an outer side surface of the inorganic layer 610 formed along the outer side surface of each of the first plurality of transparent partition walls, for example, the second transparent partition wall 520 and the fourth transparent partition wall 540.

As a result of removing a portion of the first reflective functional layer 621L, a portion of the top surface of the protection layer PTL may be exposed between 2-2 layers 621. In addition, portions of bottom surfaces of the second plurality of grooves, for example, the first groove GR1 and the third groove GR3 may be exposed between the 1-1 layers 721 and between the 1-2 layers 722.

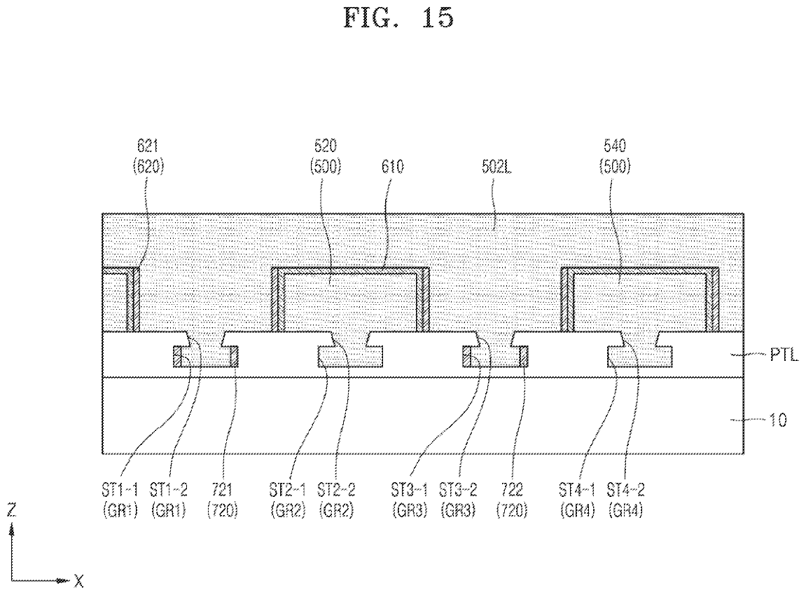

As shown in FIG. 15, the manufacturing method according to some embodiments may further include an operation of forming a second organic material layer 502L after forming the 1-1 layer 721, the 1-2 layer 722, and the 2-2 layer 621. The second organic material layer 502L may include a transparent organic material, such as polyamide (PI). The second organic material layer 502L may include the same material as the first organic material layer 501L described above. The second organic material layer 502L may be formed on the protection layer PTL while filling the second plurality of grooves.

The second organic material layer 502L may cover the top surface of the protection layer PTL exposed between the 2-2 layers 621 and may cover a second plurality of bottom surfaces exposed between the 1-1 layers 721 and between the 1-2 layers 722.

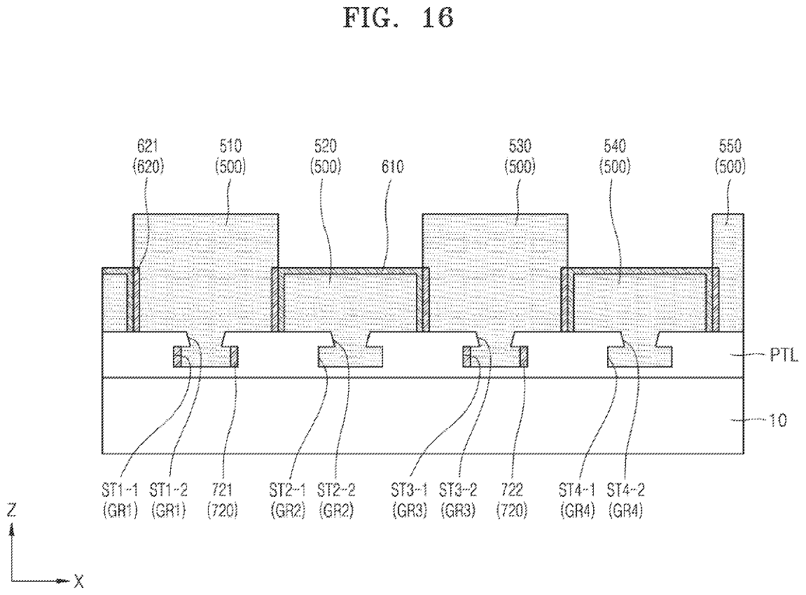

As shown in FIG. 16, the manufacturing method according to some embodiments may further include an operation of forming a second plurality of transparent partition walls, for example, the first transparent partition wall 510 and the third transparent partition wall 530 by applying an etching process to the second organic material layer 502L, after forming the second organic material layer 502L. Each of the second plurality of transparent partition walls, for example, the first transparent partition wall 510 and the third transparent partition wall 530 may be arranged between each of the first plurality of transparent partition walls, for example, the second transparent partition wall 520 and the fourth transparent partition wall 540, and the first plurality of transparent partition walls, for example, the second transparent partition wall 520 and the fourth transparent partition wall 540 and the second plurality of transparent partition walls, for example, the first transparent partition wall 510 and the third transparent partition wall 530 may be alternately arranged. The second plurality of transparent partition walls, for example, the first transparent partition wall 510 and the third transparent partition wall 530 may refer to the odd-numbered transparent partition walls described above. Shape features of the second plurality of transparent partition walls, for example, the first transparent partition wall 510 and the third transparent partition wall 530 may be the same as those of the odd-numbered transparent partition walls described above. As an example, a distance between a top surface of each of the second plurality of transparent partition walls, for example, the first transparent partition wall 510 and the third transparent partition wall 530 and the display panel 10 may be greater than a distance between a top surface of each of the first plurality of transparent partition walls, for example, the second transparent partition wall 520 and the fourth transparent partition wall 540 and the display panel 10.

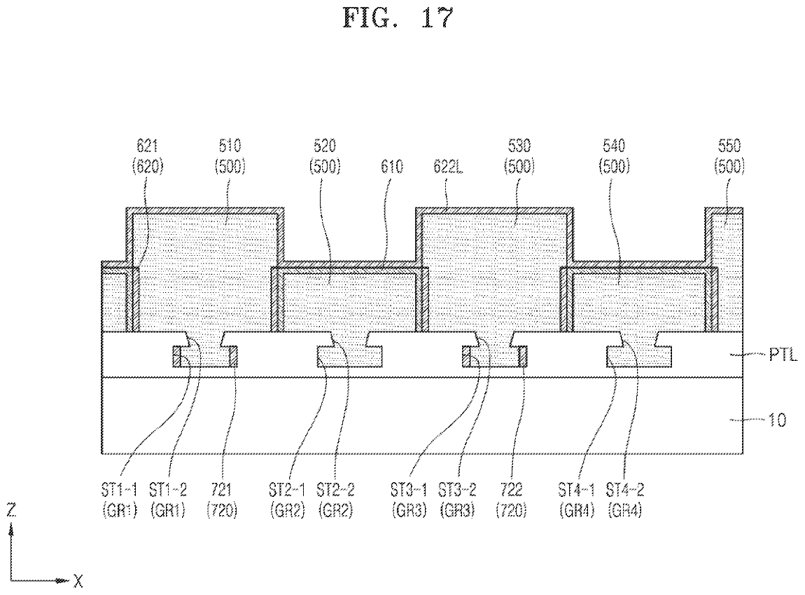

As shown in FIG. 17, the manufacturing method according to some embodiments may further include an operation of forming a second reflective functional layer 622L after forming the second plurality of transparent partition walls, for example, the first transparent partition wall 510 and the third transparent partition wall 530. The second reflective functional layer 622L may cover top surfaces of the second plurality of transparent partition walls, for example, the first transparent partition wall 510 and the third transparent partition wall 530 and portions of outer side surfaces of the second plurality of transparent partition walls, for example, the first transparent partition wall 510 and the third transparent partition wall 530. More specifically, the second reflective functional layer 622L may cover outer side surfaces of stepped portions generated by a height difference between the second plurality of transparent partition walls, for example, the first transparent partition wall 510 and the third transparent partition wall 530 and the first plurality of transparent partition walls, for example, the second transparent partition wall 520 and the fourth transparent partition wall 540. That is, the second reflective functional layer 622L may cover remaining portions of the outer side surfaces of the second plurality of transparent partition walls, for example, the first transparent partition wall 510 and the third transparent partition wall 530 that are not covered by the first plurality of transparent partition walls, for example, the second transparent partition wall 520 and the fourth transparent partition wall 540.

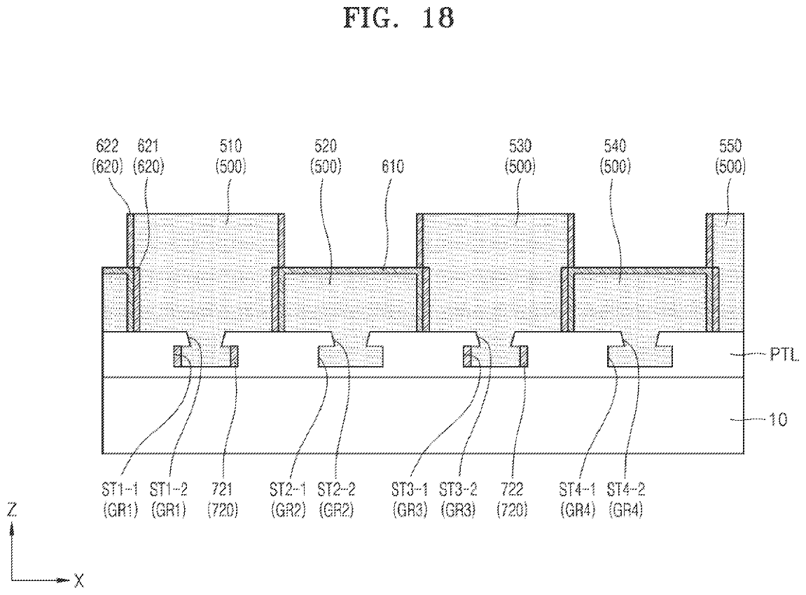

As shown in FIG. 18, the manufacturing method according to some embodiments may further include an operation of forming the 2-1 layer 622 by using an etching process, after forming the second reflective functional layer 622L. That is, the operation of forming the 2-1 layer 622 may be an operation of removing a portion of the second reflective functional layer 622L located on top surfaces of the second plurality of transparent partition walls, for example, the first transparent partition wall 510 and the third transparent partition wall 530 and another portion of the second reflective functional layer 622L located on top surfaces of the first plurality of transparent partition walls, for example, the second transparent partition wall 520 and the fourth transparent partition wall 540 by using an etching process.

The description of the manufacturing method described above is focused on the first to fourth transparent partition walls and the first to fourth grooves, the numbers of transparent partition walls and grooves according to the present embodiments are merely examples. The manufacturing method according to some embodiments may include a larger number of transparent partition walls and grooves.

According to one or more of the above embodiments, a display device with a relatively more robust structure, in which a viewing angle is controlled by blocking side light and emitting vertical light, and a method of manufacturing the display device may be implemented. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display device comprising:
a display panel;
a protection layer on the display panel and comprising a plurality of grooves each having an anchor shape, wherein the plurality of grooves comprise at least a first groove;
a 1-1 layer arranged along at least a portion of an inner side surface of the first groove; and
a plurality of transparent partition walls on the protection layer and comprising a first transparent partition wall, wherein the first transparent partition wall is arranged along the first groove and has a portion filling the first groove.

2. The display device of claim 1, further comprising a 2-1 layer arranged along at least a portion of an outer side surface of the first transparent partition wall.

3. The display device of claim 2, wherein the 1-1 layer and the 2-1 layer comprise a same material.

4. The display device of claim 1, wherein the inner side surface of the first groove comprises:
a 1-1 sub-inner side surface extending from a top surface of the protection layer in a direction toward the display panel and having a first width in a plan view; and
a 1-2 sub-inner side surface extending from a bottom of the 1-1 sub-inner side surface in the direction toward the display panel and having a second width that is greater than the first width in the plan view.

5. The display device of claim 4, wherein the 1-1 layer is arranged along the 1-2 sub-inner side surface.

6. The display device of claim 1, wherein, in a plan view, each of the plurality of grooves has a different width for each location.

7. The display device of claim 2, wherein the plurality of grooves further comprise a second groove spaced apart from the first groove.

8. The display device of claim 7, wherein the plurality of transparent partition walls further comprise a second transparent partition wall arranged on the protection layer along the second groove and having a portion filling the second groove.

9. The display device of claim 8, wherein a distance between a top surface of the second transparent partition wall and a top surface of the display panel is less than a distance between a top surface of the first transparent partition wall and the top surface of the display panel.

10. The display device of claim 8, wherein, in a plan view, an area of a top surface of the second transparent partition wall is less than an area of a bottom surface of the second transparent partition wall.

11. The display device of claim 8, wherein the 2-1 layer is between an outer side surface of the second transparent partition wall and the outer side surface of the first transparent partition wall.

12. The display device of claim 11, wherein the 1-1 layer and the 2-1 layer comprise a same material.

13. The display device of claim 8, wherein the plurality of grooves further comprise a third groove spaced apart from the second groove in a direction opposite to the first groove.

14. The display device of claim 13, wherein the plurality of transparent partition walls further comprise a third transparent partition wall on the protection layer along the third groove and having a portion filling the third groove.

15. The display device of claim 14, wherein a distance between a top surface of the third transparent partition wall and a top surface of the display panel is greater than a distance between a top surface of the second transparent partition wall and the top surface of the display panel.

16. The display device of claim 14, wherein, in a plan view, the third transparent partition wall is symmetrical to the first transparent partition wall with respect to the second transparent partition wall.

17. The display device of claim 16, further comprising a 1-2 layer arranged along at least a portion of an inner side surface of the third groove.

18. The display device of claim 17, wherein the 1-2 layer comprises a same material as the 1-1 layer.
